(19) United States
(12) Patent Application Publication
(10) Pub. No.: US 2010/0078090 A1
(43) Pub. Date: Apr. 1, 2010

(54) IMPACT SENSING MULTI-LAYERED PLASTIC MATERIAL

(75) Inventors: Michael J. Miller, Chicago, IL (US); Michael M. Mamoun, Naperville, IL (US); Daniel A. Ersoy, Lincolnwood, IL (US)

Correspondence Address: MARK E. FEJER;GAS TECHNOLOGY INSTITUTE, 1700 SOUTH MOUNT PROSPECT ROAD, DES PLAINES, IL, 60018, US

(73) Assignee: GAS TECHNOLOGY INSTITUTE, Des Plaines, IL (US)

(21) Appl. No.: 12/240,217

(22) Filed: Sep. 29, 2008

(51) Int. Cl. F16L 9/14; H01L 41/02

(52) U.S. Cl. 138/141; 310/338

(57) ABSTRACT

A multi-layer structure for sensing impacts in real-time having an inner layer of polyvinylidene fluoride having piezoelectric properties disposed between and joined with two outer layers of an electrical signal conductor.

### BACKGROUND OF THE INVENTION

1. Field of the Invention

In one aspect, this invention relates to sensors for real-time sensing of encroachments, disturbances, and impact events. In another aspect, this invention relates to a material for real-time sensing of encroachments, disturbances and impact events. In yet another aspect, this invention relates to plastic pipes for underground transmission of utilities such as natural gas having the capability of remotely alerting pipeline operators of the potential for, or actual, impact on the plastic pipe.

2. Description of Related Art

Underground pipelines are widely used to transport a variety of fluids, including oil, natural gas, water, etc., from one place to another. Such pipelines have historically been made of metals and metal alloys. In recent years, the trend has been to use plastic pipelines. Such underground systems are subject to damage from a variety of sources, both naturally occurring and man-made. For example, subsidence of the soil, local construction projects, seismic activity, and weather can all lead to defects and anomalies in the pipeline. Also, harsh environments can cause pipelines to move gradually over time, leading to defects, cracks, leaks, bumps, and other anomalies, within the interior of the pipeline. Pipeline damage can occur due to the act of a third party, i.e., a party other than the owner or operator of the pipeline. Such damage is known as “third-party damage.” When the damage due to an act of a third party causes an immediate rupture of a pipe, little can be done via on-line monitoring to prevent an ensuing incident. However, many third-party contacts with pipelines can cause damage that does not result in an immediate pipeline failure but rather cause damage that may, with time, lead to a pipe failure such as in the form of a leak or a catastrophic rupture. For example, because of the visco-elastic, time-dependent material properties of plastic pipes, surface notches, scrapes, gouges, and other defects grow with time through the pipe wall and eventually lead to a pipeline failure. Such events are referred to as slow-crack-growth (SCG) failures. Time and pressure cycling to which a pipeline might normally be subjected also may, with time, eventually lead to the occurrence of such a pipeline failure, with such a pipeline failure sometimes referred to as a “delayed failure.” In view of the above, the occurrence of such third-party contact and the effective detection thereof has proven to be a persistent problem.

Continuous monitoring of long pipelines, whether for seismic events or impacts occurring during excavation in proximity to the pipeline, is not a simple task. Damage to pipelines can be detected in a variety of ways including detection of the substance that escapes from the pipeline as the result of the damage, pressure drops in the pipeline, and impacts on the pipeline.

There are several systems and methods known to those skilled in the art for continuously monitoring the condition of underground pipelines. Acoustic monitoring of an underground pipeline may be carried out by a variety of acoustic sensors/detectors, such as geophones, accelerometers and the like. One problem with the use of acoustic means for monitoring underground pipelines is noise, both background and sensor noise, in the output signal from these means, which noise may partially or possibly completely mask the signal of interest, thereby precluding detection of the pipeline condition. For example, while sounds associated with impacts on a pipeline can be transmitted through the pipeline and detected at substantial distances from the point of contact via such highly sensitive acoustic sensors, the high sensitivity of such sensors can produce or result in a significant number of false calls arising from sources such as passing vehicles and weather conditions such as thunder.

Another system for continuously monitoring the conditions of underground pipelines or detecting remote encroachments involves the use of optical fiber technology. A long optical fiber, similar to those used in telephone systems, is buried above the pipeline. Periodically, light pulses are sent down the optical fiber. Normally, a small amount of light is reflected back to the source from each part of the fiber. When an encroachment occurs, the ground above the fiber is compressed and vibrated. This changes the optical properties of the fiber and the amount of light reflected back to the source, where it is detected. However, in addition to the substantial expense of signal processing/operating equipment employed by such systems, there are several other limitations including the fact that optical fibers can be easily damaged or fractured and cannot be bent tighter than a radius of about one foot. In addition, sensitivity decreases significantly with burial depth; and background noise and temperature have significant effects on transmission signals.

In view of the consequences of the failure of an in-ground pipeline due to third-party contact, particularly when coupled with the extensive construction related with urban expansion and encroachment of the right-of-way commonly associated with many of such in-ground pipelines, there is a need and a demand for a method and system for monitoring in-ground pipelines and, in particular, detecting contact with a pipeline and proactive warning of the potential for the occurrence of damage associated therewith. In particular, there is a need and a demand for a monitoring method and system that can effectively eliminate false calls such as may arise from at least certain non-contact events. Further, there is a need and a demand for a robust monitoring method and system that can facilitate the speedy and accurate identification of the location on an in-ground pipeline whereat such a contact has occurred.

### SUMMARY OF THE INVENTION

It is, thus, one object of this invention to provide a method and system for mitigating or reducing third party encroachments and third party impact-damage to plastic pipelines.

It is another object of this invention to provide a method and system for monitoring underground plastic pipelines for impact damage.

These and other objects of this invention are addressed by a multi-layer structure, also referred to herein as a multi-layer plaque or composite, for sensing impacts in real-time comprising an inner layer of polyvinylidene fluoride having piezoelectric properties disposed between and joined with two outer layers of a continuous electrically conductive material. The outer layers comprise a plastic material that has been doped to be electrically conductive. Any plastic that can be doped to be electrically conductive may be used and any electrically conductive material may be used to provide electrical conductivity. The use of a thermoplastic material is preferred due to the ease with which it can be heated to a temperature suitable for melting, forming, and doping. In accordance with one embodiment of this invention, the two outer layers comprise polyethylene plastic doped with metal or metallic particles. In accordance with one embodiment of this invention, the two outer layers comprise polyethylene plastic doped with carbon. The properties of this structure or plaque include the capability of detecting in real time remote impacts, mechanical disturbances or encroachments and, conversely, the capability of reacting to electrical disturbances. The structure has a continuous electrical conducting or semi-conducting property through its length, width and thickness which enables the structure to behave as a continuous electromechanical sensor. In accordance with one embodiment of this invention, the structure has a bulk electrical resistivity of about 1 ohm-meter. However, the bulk electrical resistivity may be increased or decreased for different applications. Impact or mechanical disturbance at any location along the surface of the structure causes a change in the electrical field of the material with a corresponding electrical potential change proportional to the strength of the impact or disturbance; and conversely, changes in the electrical properties of the structure cause mechanical responses. The structure is free of any electrostatic charge; that is, electrostatic charge cannot accumulate on the surface of the structure. The structure is capable of being located from above ground when disposed underground. The structure is capable of being molded, extruded, rolled or formed into a variety of shapes and forms, including ribbons, films, tapes, and conduits, such as plastic pipe, thereby allowing for easier implementation and non-obvious sensing as the entire structure acts as a sensor. The structure is resistant to impact damage, elevated field temperatures, i.e. greater than 140° F., weather exposure, UV light, and burial environments and requires only minimal signal processing equipment or training.

The substantial capabilities of the structure of this invention provide the opportunity for application in a variety of fields of use including, but not limited to, gas and water utilities, chemical and telecommunication industries, and defense applications. The utility companies can utilize the structure to detect remote impact in real time and to reduce third party encroachments. Defense applications include monitoring to detect encroachment, ground disturbances and impact detection over long distances and intelligence gathering in real time regarding the placement and detection of activity around improvised explosive devices, sensitive installations and buildings and high priority areas, perimeters or borders.

### BRIEF DESCRIPTION OF THE DRAWINGS

These and other objects and features of this invention will be better understood from the following detailed description taken in conjunction with the drawings wherein:

FIG. 1 is an exploded lateral view of a structure in accordance with one embodiment of this invention;

FIG. 2 is a diagram showing the voltage outputs of an impact sensing structure in accordance with one embodiment of this invention resulting from various drop weight impacts;

FIG. 3 is a diagram showing the baseline results of a drop weight test on a 111-ft long multi-layer structure in the form of a ribbon in accordance with one embodiment of this invention;

FIG. 4 is a diagram showing the results of a drop weight test on a multi-layer ribbon in accordance with one embodiment of this invention disposed on top of a concrete slab or foundation;

FIG. 5 is a diagram showing the results of a drop weight test on a multi-layer ribbon in accordance with one embodiment of this invention disposed on top of sand;

FIG. 6 is a diagram showing the results of a drop weight test on a multi-layer ribbon in accordance with one embodiment of this invention buried in 6 inches of sand;

FIG. 7 is a lateral view of a non-planar multi-layer structure in the form of a ribbon in accordance with one embodiment of this invention;

FIG. 8 is a transverse view of a non-planar multi-layer structure in the form of a ribbon in accordance with one embodiment of this invention;

FIG. 9 is a perspective view of a multi-layer structure in accordance with one embodiment of this invention in the form of a ribbon; and

FIG. 10 is a transverse cross-sectional view of a multi-layer structure in the form of a conduit in accordance with one embodiment of this invention.

### DETAILED DESCRIPTION OF THE PRESENTLY PREFERRED EMBODIMENTS

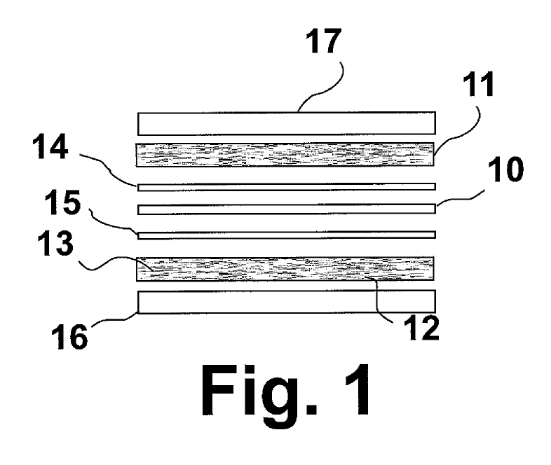

The invention claimed herein is a multi-layered structure or plaque as shown in FIG. 1 comprising a layer or plaque of polyvinylidene fluoride (PVDF) 10, which is imbued with piezoelectric properties which are induced during the creation of the multi-layer structure as will be described in more detail herein below, sandwiched between two layers or plaques 11, 12 of a continuous electrical conductor or semi-conductor. Thicknesses for the layer of PVDF are generally dictated by processing and sensitivity considerations. Thinner layers are preferred; however, thinner layers provide the opportunity for creating holes or voids during the layer production process. On the other hand, as the layer thickness increases, the sensitivity of the layer to impacts on the structure is reduced. Accordingly, within the scope of these considerations, there are no limitations on the thickness of the PVDF layer. We have found, however, that thicknesses in the range of about 5 mils to about 20 mils (0.005 inches to about 0.020 inches) work particularly well and, thus, are preferred.

Thicknesses of the two outer layers are dictated by conductivity requirements as well as sensitivity considerations. In particular, the outer layers must be thick enough to ensure structural strength and continuous electrical conductivity but not so thick as to prevent the impact energy from an impact with the structure from reaching the inner PVDF layer. The ability of the outer layers to maintain electrical conductivity at a given thickness will be dictated, at least in part, by the plastic material and dopant used to produce the layers. In accordance with one embodiment of this invention, the two layers or plaques 11, 12 comprise polyethylene plastic doped with carbon 13, which is substantially uniformly distributed throughout the polyethylene plastic. Doping of the polyethylene plastic layers with carbon or, for that matter, any other compatible electrically conductive material, prevents the generation or accumulation of an electrostatic charge because the material will conduct any such charge to ground. In accordance with one preferred embodiment, the thickness of the outer layers is at least about 30 mils (0.03 inches) and the amount of carbon in the polyethylene plastic layers is in the range of about 0.01 wt % to about 30 wt %. In accordance with one preferred embodiment, the amount of carbon is in the range of about 5.0 wt % to about 15 wt %. In accordance with one preferred embodiment of this invention, the carbon is in the form of carbon fibers. It will be appreciated, however, that other forms of dopants, e.g. carbon nanotubes, may be employed.

In accordance with one embodiment of this invention, the two layers or plaques 11, 12 comprise a continuous electrically conductive material. In accordance with one embodiment of this invention, the continuous electrically conductive material is an electrically-conductive tape. In accordance with one embodiment of this invention, the continuous electrically conductive material is an electrically conductive paint or ink. In accordance with one embodiment of this invention, the continuous electrically conductive material comprises a metallic conductor, such as Cu or Al. As used herein, the term “metallic” means metals, metal alloys, and metal-containing compounds. The use of metallic conductors enables the direct poling of the PVDF without any other plates by connecting one of the metallic conductors with a voltage source and the other metallic conductor with ground. In addition, the use of metallic conductors permits the transfer of the voltage/current generated from the PVDF layer to flow in a very low resistance conductor, thereby enabling very long distances of signal travel. In accordance with one embodiment of this invention, the multi-layer structure is sandwiched between polymer layers 16, 17 backed by mastic tape or inserted into a liner, sleeve, or plastic shrink-fit sleeve to protect the multi-layer structure from mechanical damage during installation and backfill, as well as from corrosion while buried.

### Fabrication of Inner PVDF Layer

Two different forms of PVDF, obtained from Arkema, Inc., Philadelphia, Pa., were utilized in the fabrication of a PVDF inner layer—one was a pure form of PVDF and the other was a PVDF functionalized for better bonding to other polymeric materials (referred to herein as functionalized PVDF), such as high density polyethylene (HDPE). Using a heated press, thin films of both the PVDF and functionalized PVDF resins were created. The films were then subjected to high static electric fields while at elevated temperature, a process known as poling. Poling was performed using aluminum plates placed on each side of the film and then applying heat and a static electrical field to the plates. The heat was then terminated and the material was left to cool with the static electrical field still applied. After poling, electrical connections were made using conductive tape to check the piezoelectric properties of the films. The films were connected by way of the electrical connections with an oscilloscope to measure any voltage created by physical impacts to the films. Tests involved subjecting the films to an impact load which generated a charge separation (voltage) across the PVDF material, as measured by the oscilloscope. These results demonstrate the relative ease with which the piezoelectric properties may be induced.

### Fabrication of Multi-Layer Structure

Both PVDF and HDPE have low surface energies and do not bond well to each other or to other materials. Initial experiments demonstrated that the PVDF (either the pure or functionalized form) would not bond with the HDPE and that a minimal amount of physical mixing was not sufficient to bond two layers of these materials to each other. As a result, bonding of the PVDF layer and the HDPE layers to form a multi-layer structure in accordance with one embodiment of this invention requires the use of a binder agent 14, 15. For this purpose, LOTADER®, a reactive polyethylene resin (2 propenoic acid, 2-methyl-oxiranylmethyl ester polymer with ethene), the reactivity of which is due to the presence of glycidyl methacrylate (GMA) or maleic anhydride (MAH) groups, available from Arkema, Inc., was employed. Using LOTADER as a binder, or bonding agent, a multi-layer structure in accordance with one embodiment of this invention was fabricated by creating two HDPE plaques or layers and a thin sheet of PVDF and pressing them together with LOTADER pellets in between the layers. The layers were pressed together by application of 15 tons of force in a press heated to and maintained at a temperature of about 172° C. The result is a multi-layer structure in which the PVDF layer has not been imbued with piezoelectric properties. However, the multi-layer structure was found to be conductive across the PVDF layer and, thus, could not be poled. To be poled, the PVDF layer must insulate the outer two layers of HDPE from each other. It was determined that fabrication of the multi-layer structure using LOTADER in the form of pellets was responsible for the conductions across the PVDF layer. Mitigation of the conduction was attempted by first pressing the LOTADER pellets to form a flat layer. Although somewhat effective, this did not fully address the conduction problem. Further experimentation established that the conductions/shorts also were the result of unevenness in the thickness of the PVDF layer. Increasing the thickness of the PVDF layer resulted in a multi-layer structure having an inner PVDF layer which could be property poled.

Successful poling of the PVDF layer requires a controlled source for the required high voltage (HV). Initial poling attempts using an HV source which applies a constant 8 kV signal produced shorts at the edges of the layers manifested in the form of sparks through the air. To address this issue, an HV holiday detector having a variable HV source with a range of about 0.1 kV to about 15 kV was used. The use of the HV holiday detector allows for control of the poling voltage, thereby enabling it to be tailored to the specific PVDF layer being poled. This also allows for poling at the maximum voltage for a given PVDF layer before shorts occur.

Using the more precise HV holiday detector/poling method described herein above, it was determined that shorts often occurred within the interior of the multi-layer structure that still limited the high voltage application. To generate more impact-sensitive structures, higher voltage poling is required. To this end, an intermediate quality control step was introduced into the fabrication process. In this step, a layer of HDPE containing carbon fiber material was pressed with LOTADER and a PVDF sheet to generate a “half-plaque”. This step allows the half-plaque to be checked with the HV holiday detector to verify that the PVDF layer is sufficiently uniform to withstand higher poling voltages. In addition, by creating a half-plaque in this manner, the PVDF layer maintains a smooth flat surface because it is in direct contact with the aluminum plate. With this intermediate quality control step, full sized multi-layer structures were fabricated that did not have internal shorts during poling. However, poling voltage was still limited by shorting at the edges of the multi-layer structure caused by the dielectric breakdown of air. To eliminate the electric shorts at the edges, glue, tape, and plastic were used to insulate the edges of the structures. The highest poling voltage obtained was 3.0 kV. The thickness of the PVDF could withstand voltages as high as 10.0 kV. However, 3.0 kV is sufficient enough to induce piezoelectric properties in the multi-layer structure.

### EXAMPLE

In this example, 30 grams of PVDF functionalized for enhanced bonding in the form of pellets was pressed at 180° C. with a force of 16 tons using an automated Wabash press, producing a thin sheet of the functionalized PVDF material having a thickness of about 0.01 inches. Two sheets were produced in this manner for the final multi-layer structure.

Two conductive HDPE layers were fabricated by pressing HDPE grinds mixed with carbon fiber. Each conductive layer was made by mixing 250 grams of HDPE with 25 grams of carbon fiber in a blender. (As much as about one-half of the carbon fiber may be lost during the mixing process.) The blended mixture was placed in a ⅛ inch thick picture frame press mold. With a cover placed on top of the picture frame, the mold was heated to 150° C. and pressed with a 25 ton force. The temperature was then raised to 180° C. and the picture frame mold repressed again at 25 tons. The resulting layer was allowed to cool under ambient conditions. The result was a ⅛-inch thick HDPE layer that is inherently electrostatically free which is capable of acting as a continuous semi-conductor to transmit an electrical signal.

To prevent the LOTADER from penetrating the PVDF layer, the LOTADER is pressed to change its shape from a pellet to a plate shape. This may be achieved by pressing small batches of the LOTADER; the amount to be pressed depends on the pressure/force capacity of the press. In this example, 1 gram or less of the LOTADER was pressed using a 30 ton force at ambient conditions. Using this technique, 20 grams of the LOTADER were pressed into a plate shape, which was used in the fabrication of the final multi-layer structure.

To allow for better control of the bonding of the PVDF layer to each of the two outer HDPE layers containing carbon fibers, two “half-plaques” were first fabricated as follows. First, the flat LOTADER was mixed with a small amount of carbon fiber to cause the bonding agent to become electrically conductive. The resulting mixture was then evenly spread over one of the two conductive ⅛-inch thick HDPE layers. A pressed functionalized PVDF sheet was placed over the LOTADER-carbon fiber mixture covering the conductive HDPE layer. The conductive HDPE layer having the LOTADER-carbon fiber mixture and the pressed functionalized PVDF sheet was then placed in an aluminum ⅛-inch picture frame mold, putting the functionalized PVDF sheet in direct contact with the aluminum cover plate of the picture frame mold used for pressing and forcing it to remain flat.

The half-plaque, comprising the conductive HDPE layer, LOTADER-carbon fiber mixture, and functionalized PVDF sheet was placed in a ⅛-inch picture frame mold. The half-plaque materials were then placed between two aluminum plates for pressing using the heated Wabash press. The preset temperatures were 150° C. for the side in contact with the functionalized PVDF sheet and 172° C. for the side in contact with the HDPE layer. After insertion into the press, the temperatures initially dropped. Once the HDPE side recovered to 170° C., the press was activated to 6 tons of pressure for 1 minute after which the water cooling was activated until the half-plaque cooled to room temperature. The other half-plaque was then processed in the same manner.

After fabrication of the half-plaques, an HV holiday detector was used to search for thin spots or pin holes, if any, in the PVDF layer. For this test, the HV detector was set to 7.5 kV. After completion of the quality control step, the two half-plaques were pressed together to form the final single multi-layer structure. This was accomplished by placing the two half-plaques, suitably oriented to provide a final multi-layer structure in which the outer layers comprise HDPE, in a ¼-inch picture frame mold. The mold was then pressed in the Wabash press under a 3-ton force at a temperature of 180° C. After the initial temperature drop and subsequent recovery, water cooling was turned on until the temperature returned to ambient.

After completion of the fabrication of the multi-layer structure, the structure was electrically poled. The first step was to confirm that the structure was non-conductive across the center PVDF layer with 1000 volts applied. Next, the edges of the structure were isolated as well as possible by cutting off small strips and taping with electrical tape. The structure was then placed between two aluminum plates connected with the HV holiday detector. The plates were heated to 120° F. and the HV detector turned on. The voltage of the detector was slowly increased until shorting occurred along the edge of the structure.

To induce the required piezoelectric properties into the final single multi-layer structure, heat and high voltage were applied to the structure for 1 hour. After 1 hour of poling, the heat was turned off while the voltage remained. After the structure returned to room temperature, the high voltage was turned off. At this point, the multi-layer structure was completely fabricated and imbued with impact-sensing capabilities.

As an alternative, the multi-layer structure of this invention may be fabricated using a single half-plaque pressed with LOTADER and an HDPE layer to create the final product. Using only one half-plaque eliminates the use of a second sheet of PVDF, thereby reducing the thickness of the PVDF layer and increasing the piezoelectric sensitivity of the end-product multi-layer structure.

To prevent the occurrence of shorting along the edges of the multi-layer structure in accordance with one embodiment of this invention, a non-conductive edge may be added to one of the outer HDPE layers. This may be accomplished by removing a portion of the entire periphery of one of the outer conducting HDPE layers and replacing it with non-conducting HDPE.

To determine the impact-sensing capabilities of the multi-layer structure of this invention, a series of impact tests were performed on multi-layer structures produced in accordance with the above described method. The structures were tested by monitoring the electrical state of the structures as they were struck by an object. Electrical connections were made with conductive tape or small nails inserted into the structure on either side of the center PVDF layer. One electrical lead was attached to the probe of an oscilloscope and the other lead was connected to ground. The oscilloscope is used to monitor any charge separation by the center PVDF layer as it is conducted to the oscilloscope through the outer conductive HDPE layers of the structure.

Initial testing of the multi-layer structures involved simple hand-striking of the structure to establish the presence of piezoelectric properties. The various methods of hand-striking generated voltages ranging from a few mV to more than 5.0 volts. However, because they were not well controlled, the impacts did not produce a consistent response.

More controlled tests were conducted using a spring-loaded nail set to strike the structures produced using different poling voltages. The procedure involved pressing the nail set against the structure until an internal spring released, causing an “impact”. The nail strikes produced an impact voltage of 360 mV for a 2 kV poled structure compared with 2000 mV for a multi-layer structure poled at 10 kV. These results demonstrate the importance of the poling voltage. By increasing the poling voltage fivefold, the sensitivity of the multi-layer structure was also increased fivefold.

Testing was also performed by dropping a non-conductive object, such as a wooden block, onto a multi-layer structure in accordance with one embodiment of this invention and the electrical response of the oscilloscope noted. However, the peak-to-valley readings of the oscilloscope from these impacts could not be correlated to an exact impact strength.

ASTM test method number ASTM G-14 entitled “Standard Test Method for Impact Resistance of Pipeline Coatings (Falling Weight Test)” sets forth a method for performing drop weight tests for the purpose of determining the impact resistance of pipeline coatings. The test utilizes a calibrated weight having a hemispherical tip dropped through a tight fitting tube onto the impact area. To evaluate the responsiveness of the multi-layer structure of this invention, the test procedure was modified by placing an aluminum “puck” in the impact area to spread the force of the impact. This testing produced higher impact energies and more consistent strikes.

Testing was carried out on three different multi-layer structures produced in accordance with the above described method.

### Example 1

In this example, a weight of 146.7 grams was dropped through a 15-inch tall tube onto a multi-layer structure of this invention (referred to herein as “plaque A”), resulting in an impact energy of 4.9 in.*lbs. The weight drop was carried out on 2-inch by 2-inch grid sections of the multi-layer structure having nine grid sections. The resulting peak-to-valley voltage for a given impact, as monitored by the oscilloscope, was recorded. A minimum of three drops were made on the different grid sections of the multi-layer structure following the grid pattern, and the resulting voltages averaged for each grid section. The results are shown in Table 1 for each of the 2-inch squares.

TABLE 1
Plaque A Poled at 10 kV, Response to Drop Weight Test,
4.9 in. * lbs Impact Energy
Impact Voltage (V) in Grid Sections of Plaque A

| | | |
|---|---|---|
| 3.0 | 3.7 | 3.3 |
| 3.3 | 6.9 | 4.5 |
| 3.9 | 4.6 | 4.0 |

### Example 2

In this example, drop weight testing was performed as in Example 1 on a second multi-layer structure (referred to herein as “plaque B”). The results, similar to the results obtained with plaque A, are shown in Table 2.

TABLE 2
Plaque B Poled at 10 kV, Response to Drop Weight Test,
4.9 in. * lbs Impact Energy
Impact Voltage (V) in Grid Sections of Plaque B

| | | |
|---|---|---|
| 4.0 | 4.6 | 4.7 |
| 4.6 | 5.8 | 5.5 |
| 3.3 | 5.8 | 3.7 |

As previously indicated, one of the applications of the multi-layer structure of this invention is for use in underground plastic utility pipelines to enable detection of third party impacts on the pipeline. During installation, sections of plastic pipe may be joined together using heat fusion with or without the use of a coupling. Butt heat fusions utilize an alignment device, scraping tool, and heater iron to fuse two pieces of pipe together without the aid of a coupling. Thus, tests were performed to determine the effect, if any, of butt heat fissions on the impact sensing ability of the multi-layer structure of this invention. For these tests, two pieces of plaque B were manually heat fused together and drop weight tests performed using a 146 gram weight from 15 inches above the fused plaque to produce a 4.9 in.*lbs. impact. The results, shown in Table 3, show that the multi-layer structure retains the impact sensing capability after the joining of two pieces by butt heat fusion. Differences in response are attributed to unevenness in the impacts due to inconsistencies in manually making the fusion joint and differences in the sensitivity of various areas of the plaque arising out of non-uniformities in the creation of the plaque.

TABLE 3
Plaque B After Fusion, Response to 4.9 in. * lbs Impact Energy
Impact Voltage (V)

| | Left of Fusion | Right of Fusion |
|---|---|---|
| Average | 1.5 | 3.2 |
| Standard Deviation | 0.3 | 1.0 |

### Example 3

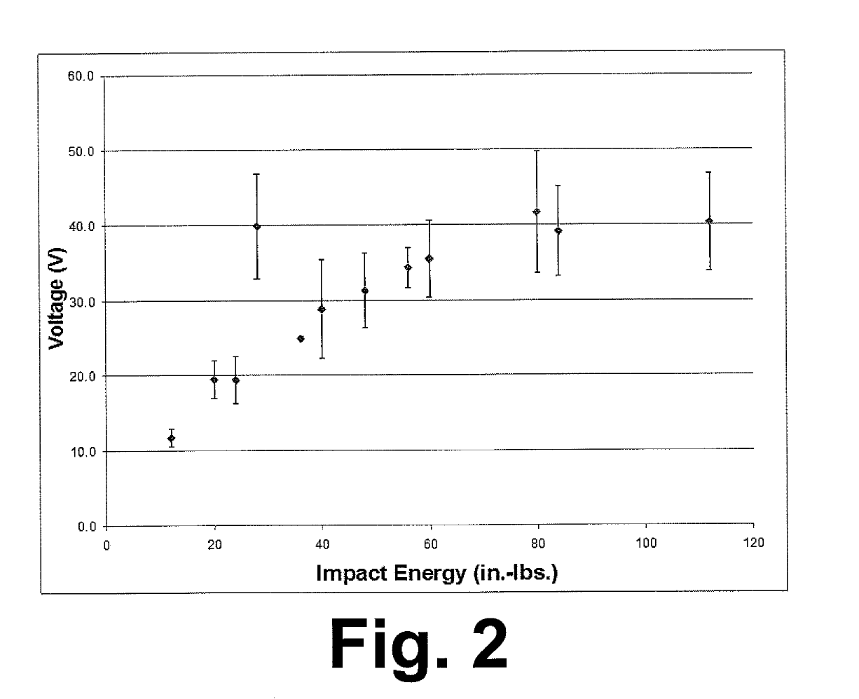

In this example, drop weight testing was performed on a multi-layer structure created in accordance with the above described method, but with the poling increased to 11 kV (referred to herein as “plaque C”), using the modified ASTM G-14 procedure. The baseline impact for this test was greater than in the previous drop weight tests. The results of this test are shown in FIG. 2. The results show that large signals can be generated by the impact-sensing multi-layer structure. The impact test results also indicate that the voltage increases nearly linearly with an increase in impact energy. The larger impacts, above about 80 in.*lbs., did not register the full voltage difference due to a range limitation of 50 V for the oscilloscope employed in the test. This limitation may account for the leveling off of the increasing voltage with increasing impact.

Having determined the functionality of the multi-layer structure of this invention, tests were conducted to determine the distances over which a signal generated by an impact would be transmitted along the length of a multi-layer structure in accordance with this invention made in the form of a ribbon. Such a multi-layer ribbon may be produced by hot rolling the PVDF middle layer at a high pressure to orient the electrical dipoles along a preferred axial direction followed by application and bonding of two outer conductive layers of an electrically conductive tape, sandwiching the hot-rolled PVDF layer there between. The multi-layer ribbon is then electrically poled at an elevated temperature in an environmental chamber using a high-voltage electric-field generator.

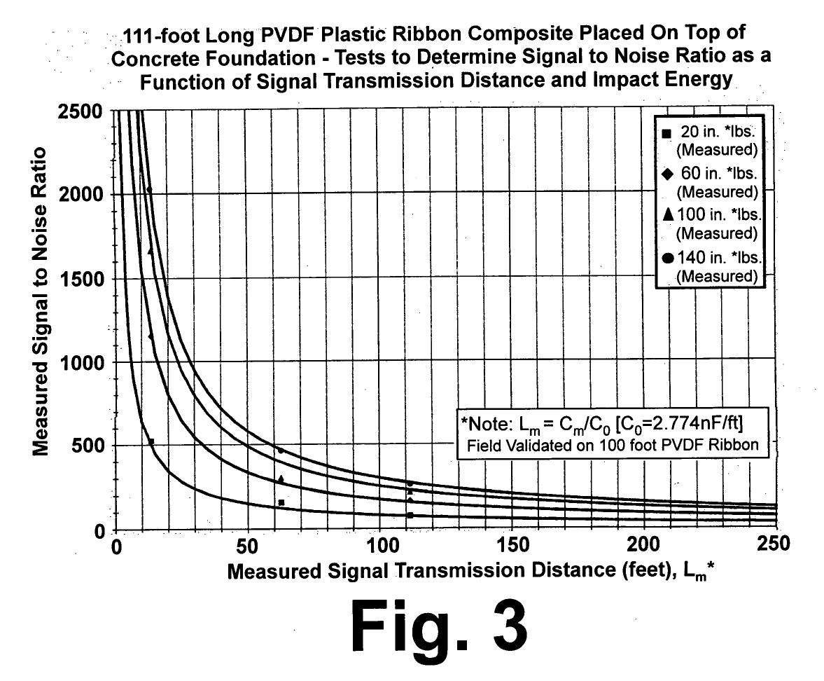

Tests were conducted on a multi-layer structure in accordance with one embodiment of this invention in the form of a composite ribbon 111 feet long by 4 inches wide having a thickness of about 0.004 inches placed on top of a concrete floor. The results, shown in FIG. 3, show that, at a distance of 111 feet, an impact energy of 60 in.*lbs. generated a signal-to-noise (S/N) ratio greater than about 200 and an impact energy of 100 in.*lbs. generated a S/N greater than about 300.

Tests were conducted on the composite 111-ft long ribbon connected with an electrical analog circuit board to simulate ribbon lengths up to about 4500 feet for three different situations—one in which the multi-layer structure was disposed on top of a concrete foundation (Case A), one in which the multi-layer structure was disposed on top of sand (Case B), and one in which the multi-layer structure was buried six inches deep in sand (Case C). The circuit board was custom designed using the measured electrical properties, i.e. resistance and capacitance, of the PVDF composite ribbon to physically simulate the electrical transmission properties of the ribbon for various extended lengths, e.g. 250 ft., 500 ft., 1000 ft., 1500 ft., etc. For each case, a drop weight test was performed at three different impact energies—60, 100, and 140 in.*lbs. The results were used to calculate the signal transmission distance in accordance with the formula

Lₘ=Cₘ/C₀

where Cₘ is the measured capacitance (nF), C₀=2.73 nF/ft, and Lₘ is the signal transmission distance in feet.

TABLE 4
Transmission Distances as Function of Ribbon Location

| | | | Signal to Noise | | |
|---|---|---|---|---|---|
| | | | 2 | 4 | 6 |
| | | | Extrapolated Signal | | |
| | PVDF Ribbon | Impact Energy | Transmission | | |
| Case | Location | (in. * lbs.) | Distance (Feet) | | |
| A | On top of | 60 | 10,984 | 2,820 | 1,797 |
| | Concrete | 100 | 16,351 | 7,882 | 5,144 |
| | Foundation | 140 | 19,574 | 9,436 | 6,158 |
| B | On Top of Sand | 60 | 5,408 | 2,460 | 1,552 |
| | | 100 | 7,255 | 3,471 | 2,255 |
| | | 140 | 9,747 | 4,663 | 3,029 |
| C | Buried in Sand, | 60 | 2,974 | 1,365 | 866 |
| | 6 Inches | 100 | 4,396 | 2,017 | 1,279 |
| | | 140 | 6,286 | 2,807 | 1,752 |

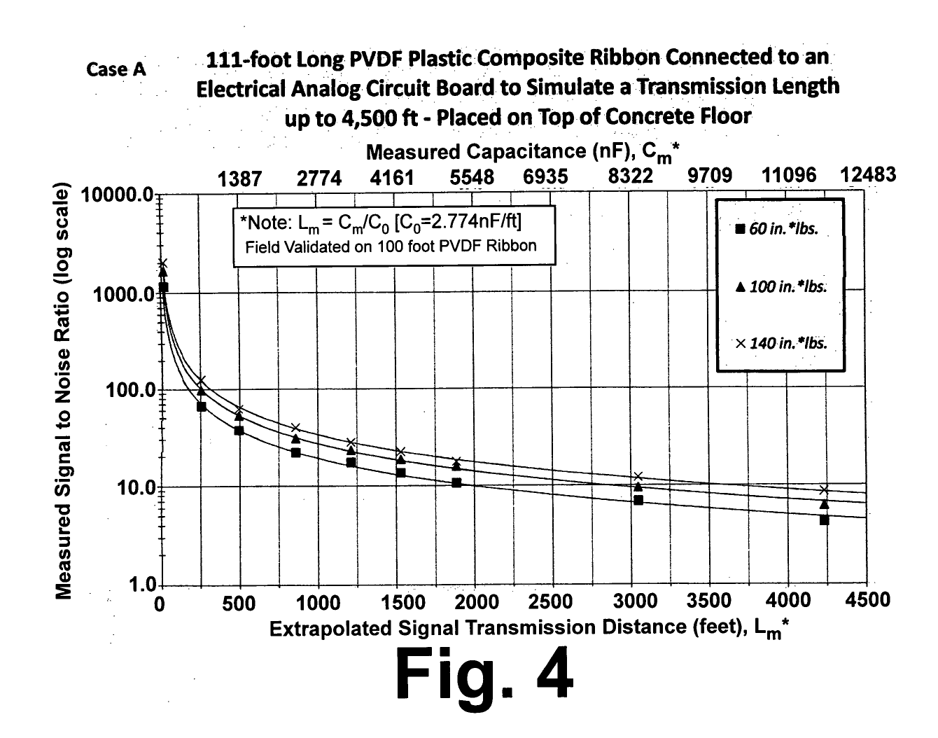

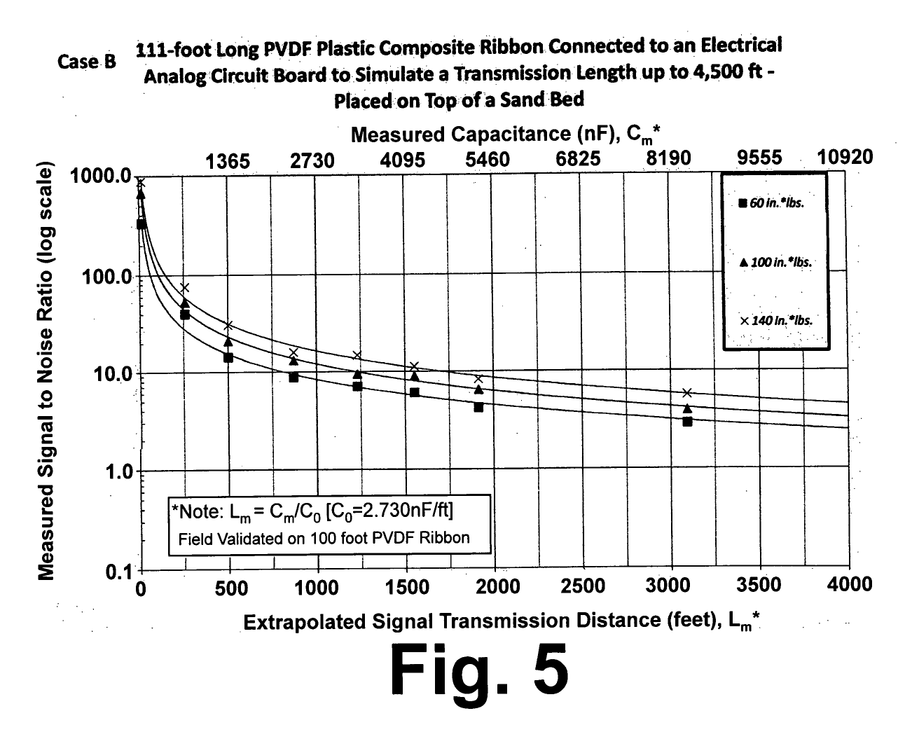

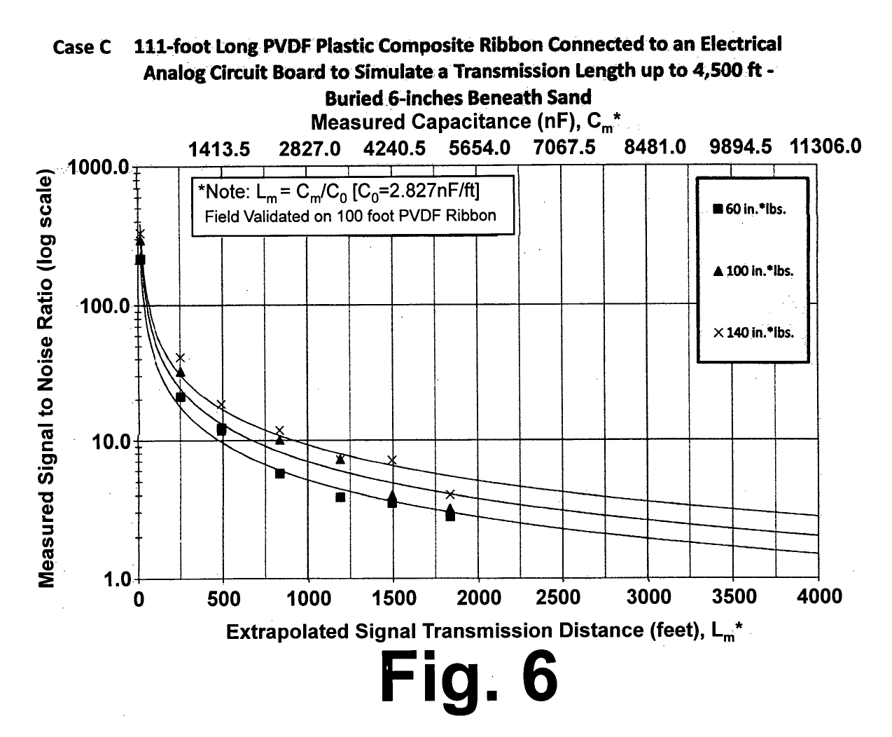

As shown in Table 4 and FIGS. 4-6, for each situation, the transmission distance is seen to increase with increases in impact energy and the distance is seen to decrease with increases in signal-to-noise ratio. In addition, the results show the effect of disposition of the multi-layer ribbon on signal transmission distance with the distance being the lowest for the ribbon buried in sand and highest for disposition on a solid (concrete) surface. Most importantly, the results demonstrate the high sensitivity of the ribbon to detect an impact or encroachment and the ability of the ribbon to generate electrical signals that can travel thousands of feet. For example, for a S/N ratio as high as 4, the transmission distance is 2807 feet for a 140 in.*lb impact energy.

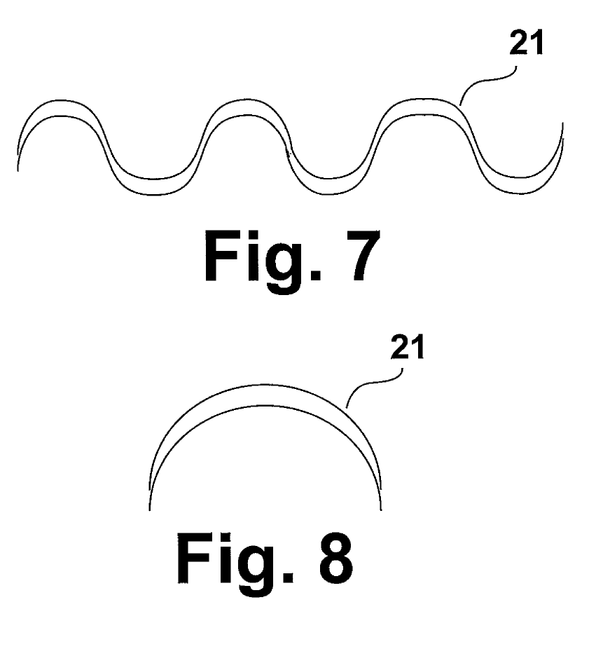

The test results shown in FIGS. 3-6 are for a substantially flat, or planar, composite ribbon. We have found, however, that ribbons which are not flat, e.g. longitudinally corrugated or transversely arced as shown in FIGS. 7-8, produce a greater S/N ratio at a given distance and a given impact energy than the flat composite ribbons, i.e. greater sensitivity.

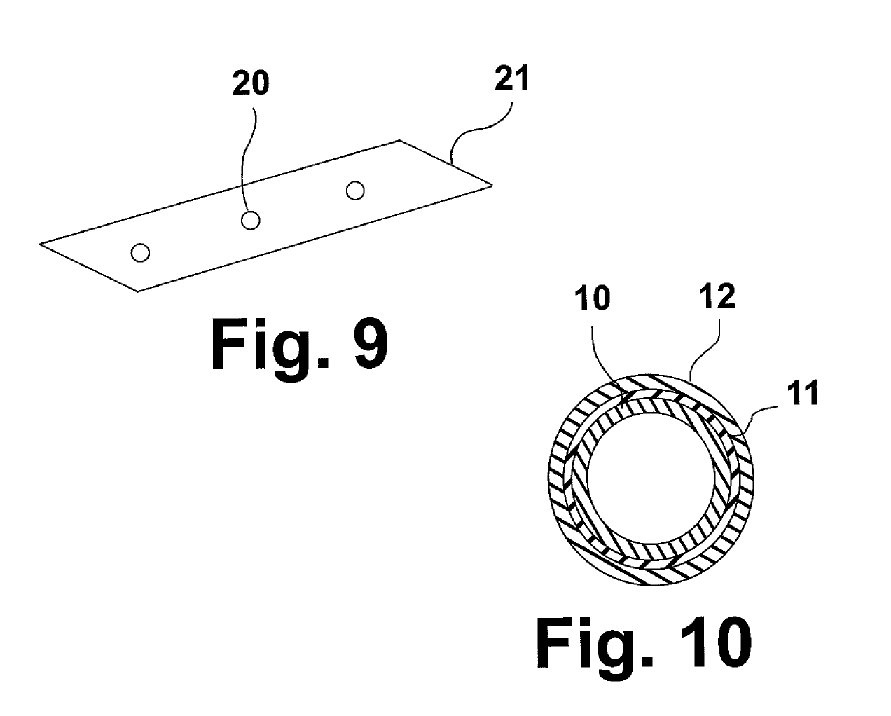

It will be appreciated that, in addition to detecting the occurrence of an impact or encroachment event, knowing the location of the event is very desirable. Determining the location of the impact or encroachment may be achieved in accordance with one embodiment of this invention by the attachment of a plurality of voltage sensors 20 a given distance apart along the length of the multi-layer ribbon 21 as shown in FIG. 9. When an impact or encroachment event occurs, the location of the event is the location of the voltage sensor producing the greatest output signal. Alternatively, the location of the impact or encroachment event may be determined using a pair of spaced apart voltage sensors and comparing the voltages measured at the sensors. As the test results show, the voltage generated by an impact or encroachment event attenuates with distance from the site of the event. Thus, the ratio of the voltages measured may be used to determine the location of the event between the two voltage sensors. For example, if the voltages measured at the two sensors are the same, the event would have occurred at a distance approximately half way between the two sensors.

As previously indicated, the multi-layer structure of this invention is capable of being molded, extruded, rolled or formed into a variety of shapes and forms. FIG. 10 shows a multi-layer structure in the form of a conduit such as may be employed for the transmission of fluids such as natural gas and water. It will be appreciated by those skilled in the art that the structure is capable of being formed by any number of methods into virtually any shape, and such methods and shapes are deemed to be within the scope of this invention.

While in the foregoing specification this invention has been described in relation to certain preferred embodiments thereof; and many details have been set forth for purpose of illustration, it will be apparent to those skilled in the art that the invention is susceptible to additional embodiments and that certain of the details described herein can be varied considerably without departing from the basic principles of the invention.

We claim:

1. A multi-layer structure for sensing impacts in real-time comprising:
an inner layer of polyvinylidene fluoride having piezoelectric properties disposed between and joined with two outer layers of a plastic material comprising conduction means for conducting an electrical signal.

2. The multi-layer structure of claim 1, wherein said two outer layers of said plastic material are doped with an electrically conductive dopant.

3. The multi-layer structure of claim 2, wherein said electrically conductive dopant comprises carbon.

4. The multi-layer structure of claim 1, wherein said plastic material is a thermoplastic material.

5. The multi-layer structure of claim 2, wherein said electrically conductive dopant is substantially uniformly dispersed throughout said plastic material.

6. The multi-layer structure of claim 3, wherein said carbon comprises in a range of about 0.01 wt % to about 30.0 wt % of said outer layers of said plastic material.

7. The multi-layer structure of claim 3, wherein said carbon is in a form of carbon fibers.

8. The multi-layer structure of claim 1, wherein said layers are joined together by heat-fusion.

9. The multi-layer structure in accordance with claim 1, wherein said layers are joined together by a binding agent.

10. The multi-layer structure of claim 9, wherein said binding agent is doped with carbon fibers substantially uniformly dispersed throughout said binding agent, rendering said binding agent electrically conductive.

11. The multi-layer structure of claim 1, wherein said polyvinylidene fluoride is functionalized for enhanced adhesion to other polymeric materials.

12. The multi-layer structure of claim 1, wherein said plastic material is polyethylene.

13. A plastic conduit for fluid transmission comprising:
a multi-layer conduit wall comprising two layers of a plastic material comprising conduction means for conducting an electrical signal and a polyvinylidene fluoride layer having piezoelectric properties disposed between and joined with said two layers of plastic materials.

14. The plastic conduit of claim 13, wherein said two layers of plastic material are doped with an electrically conductive dopant.

15. The plastic conduit of claim 14, wherein said electrically conductive dopant is carbon.

16. The plastic conduit of claim 15, wherein said carbon is substantially uniformly dispersed throughout said plastic material.

17. The plastic conduit of claim 15, wherein said carbon comprises in a range of about 0.01 wt % to about 30 wt % of said two layers of said plastic material.

18. The plastic conduit of claim 15, wherein said carbon is in a form of carbon fibers.

19. The plastic conduit of claim 13, wherein said layers are joined together by heat-fusion.

20. The plastic conduit of claim 13, wherein said layers are joined together by a binding agent.

21. The plastic conduit of claim 13, wherein said polyvinylidene fluoride is functionalized for enhanced adhesion to other polymeric materials.

22. A multi-layer structure for sensing impacts in real-time comprising:
an inner layer of polyvinylidene fluoride having piezoelectric properties disposed between and joined with two outer layers of a continuous electrical signal conductor.

23. The multi-layer structure of claim 22, wherein said continuous electrical signal conductor of one of said outer layers comprises a different conductive material than said continuous electrical signal conductor of the other of said outer layers.

24. The multi-layer structure of claim 22, wherein said continuous electrical signal conductor comprises at least one continuous metallic conductor.

25. The multi-layer structure of claim 22, wherein said continuous electrical signal conductor is an electrically conductive tape.

26. The multi-layer structure of claim 22, wherein said continuous electrical signal conductor comprises a plastic material doped with carbon.

27. The multi-layer structure of claim 22 further comprising at least one outer polymeric protective layer enclosing said inner layer and said two outer layers of a continuous electrical signal conductor.

28. The multi-layer structure of claim 27, wherein said at least one outer polymeric protective layer is selected from the group consisting of a sleeve, tape, shrink-sleeve, liner, or polymeric strips.
